(19) United States
(12) Patent Application Publication
(10) Pub. No.: US 2011/0286611 A1
(43) Pub. Date: Nov. 24, 2011

(54) DIGITAL AMPLIFIER

(75) Inventor: Keiji KATORI, Chiba-ken (JP)

(73) Assignee: JVC KENWOOD HOLDINGS, INC., Yokohama-shi (JP)

(21) Appl. No.: 13/050,574

(22) Filed: Mar. 17, 2011

(30) Foreign Application Priority Data
May 24, 2010 (JP) 2010-118750

(51) Int. Cl. H03F 99/00; H03F 3/217

(52) U.S. Cl. 381/120; 330/251

(57) ABSTRACT

A digital amplifier is described with decreased high-frequency noise current flowing into GND via a capacitor in a low-pass filter output. Consequently output sound quality is improved because AC loops of noise current that occur are balanced while each switch is turned on.

A speaker has two ends connected to the output of the amplifier. The DC power circuit has, for example, a B+ (+power supply) terminal and the GND terminal. One low-pass filter of the digital amplifier has capacitors C1 and C3, and the other low-pass filter has capacitors C2 and C4. Capacitors C1 and C2 are connected between a speaker and GND. Capacitors C3 and C4 are connected between a speaker and B+.

### CROSS REFERENCE TO RELATED APPLICATIONS

This application claims priority based on 35 USC 119 from prior Japanese Patent Application No. P2010-118750 filed on May 24, 2010, entitled “DIGITAL AMPLIFIER”, the entire contents of which are incorporated herein by reference.

### BACKGROUND OF THE INVENTION

1. Field of the Invention

The present invention relates to a digital amplifier for audio players.

2. Description of the Related Art

JP Patent Application Publication No. 2005-348288 (patent document 1) describes a digital amplifier that prevents pop noises occurring at a beginning or at an end of muting. In the digital amplifier, switching devices are connected in parallel to a speaker. Then, the switching devices are turned on for a predetermined time just before oscillation begins or just before oscillation steps, which causes a short circuit (see FIG. 4 in the patent document 1). In addition, two capacitors connected in parallel are an used as a low-pass filter. And then, one capacitor is always operated. The other capacitor is operated for a predetermined time just before a start or an end of an oscillation action by turning on a switching device which is serially connected to the capacitor (see FIG. 6 in patent document 1).

FIG. 1 is a circuit diagram showing a conventional digital amplifier 70. A low-pass filter in the digital amplifier described in patent document 1 has the same structure as the one shown in FIG. 1. Each element in digital amplifier 70 corresponds to an element in digital amplifier 10. Details are given in the description of digital amplifier 10.

A low-pass filter in amplifier 1 is composed of coil L1 and capacitor C1. A low-pass filter in amplifier 2 is composed of coil L2 and capacitor C2. Two ends of speaker 19 are connected to the output of amplifier 1 and amplifier 2. Amplifier 1 and amplifier 2 are connected with BTL (Bridged Transless) connection.

FIG. 2 and FIG. 3 each show a simplified diagram representing an AC (Alternate Current) noise current loop in a circuit with an LC filter while FET (Field Effect Transistor) 12 or 13 in digital amplifier 70 in FIG. 1 is turned on. FIG. 2 and FIG. 3. are simplified by omitting the circuit diagram of FET 14 and 15 for speaker 19 from the figures.

when capacitor C1 is connected to the GND (Ground) pattern, inaudible high-frequency noise current among pulse components in the PWM (Pulse Width Modulation) signal flows into the GND pattern. This degrades sound quality since GND experiences by high-frequency noise.

An output stage of the digital amplifier generates a PWM signal output by alternately turning on FET 12 or FET 13, which can be CMOS (complementary metal oxide semiconductor) devices. There is a big difference in an AC loop of the noise current between when FET 12 is turned on and when FET 13 is turned on due to capacitor C1 of the output LC filter, which is connected to GND. This difference increases impact on other circuits due to electromagnetic radiation that arises from loop noise, which degrades sound quality. In addition, since the electromagnetic radiation of noise impacts other circuits, as the size of loop is increased, the impact on the other circuits also increases, which degrades sound quality.

### SUMMARY OF THE INVENTION

An object of embodiments is to provide a digital amplifier that decreases high-frequency noise current flowing into GND via a capacitor in a low-pass filter output and that solves an unbalance in the AC loop of a noise current occurring while each switching device is turned on.

According to a digital amplifier of an embodiment, a switching circuit that has two switching devices connected in series, and a capacitor circuit which has two capacitors connected in series are connected to both ends of a power drive unit. A connection point of the two capacitors is structured as the amplifier output terminal, which is an output terminal of a low-pass filter.

A digital amplifier of a first embodiment comprises: a switching circuit having two switching devices connected in series, wherein both ends are connected to an amplifier power drive unit; a gate drive circuit switching the two switching devices on and off alternately; two capacitors connected in series to ends of the switching circuit; a coil connecting an intermediate point between the two switching devices and an intermediate point between the two capacitors; and a output of the digital amplifier connected at an intermediate point between the two capacitors.

A digital amplifier of a second embodiment comprises: a first amplifier unit, comprising; a first switching circuit having two switching elements connected in series, wherein both ends of the switching circuit are connected to an amplifier power drive unit; a first gate driver circuit switching the two switching devices on and off alternately; two capacitors connected in series between both ends of the first switching circuit; a coil connecting an intermediate point between the two switching devices and an intermediate point between the two capacitors; and a first amplifier output unit connected in between the two capacitors; a second amplifier unit, comprising; a second switching circuit having two switching elements connected in series, wherein both ends of the switching circuit are connected to an amplifier power drive unit; a second gate driver circuit switching the two switching devices on and off alternately; two capacitors connected in series between both ends of the second switching circuit; a coil connecting an intermediate point between the two switching devices and an intermediate point between the two capacitors; and a second amplifier output unit connected in between the two capacitors; and a signal supplier unit for supplying an antiphase signal to the first gate driver circuit and the second gate driver circuit.

According to embodiments, sound output quality improves because AC loops are balanced while each switching device is turned on.

### BRIEF DESCRIPTION OF THE DRAWINGS

FIG. 1 is a circuit diagram to illustrate a conventional digital amplifier.

FIG. 2 is a simplified circuit diagram to illustrate an AC loop of a noise current in a circuit having an LC filter in the digital amplifier shown in FIG. 1 while a high-side FET is turned on.

FIG. 3 is a simplified circuit diagram to illustrate an AC loop of a noise current in a circuit having an LC filter in the digital amplifier shown in FIG. 1 while a low-side FET is turned on.

FIG. 4 is a circuit diagram to illustrate a digital amplifier circuit embodiment.

FIG. 5 is a simplified circuit diagram to illustrate an AC loop of a noise current in a circuit having an LC filter in the digital amplifier shown in FIG. 4 while a high-side FET is turned on.

FIG. 6 is a simplified circuit diagram to illustrate an AC loop of a noise current in a circuit having an LC filter in the digital amplifier shown in FIG. 4 while a low-side FET is turned on.

FIG. 7 is a circuit diagram to illustrate a digital amplifier that has a single-ended output driven by a double power supply.

FIG. 8 is a circuit diagram to illustrate a digital amplifier that has a single-ended output driven by a single power supply.

### DETAILED DESCRIPTION OF EMBODIMENTS

FIG. 4 shows a circuit diagram of digital amplifier 10. FIG. 4 includes speaker 19 and DC power circuit 18, which are external devices of digital amplifier 10. For instance, digital amplifier 10 may be utilized with audio devices. Further, digital amplifier 10 may be furnished to each audio channel when utilized with an audio device having plurality of speakers such as right and left speakers. Digital amplifier 10 may be implemented as a single IC (Integrated circuit).

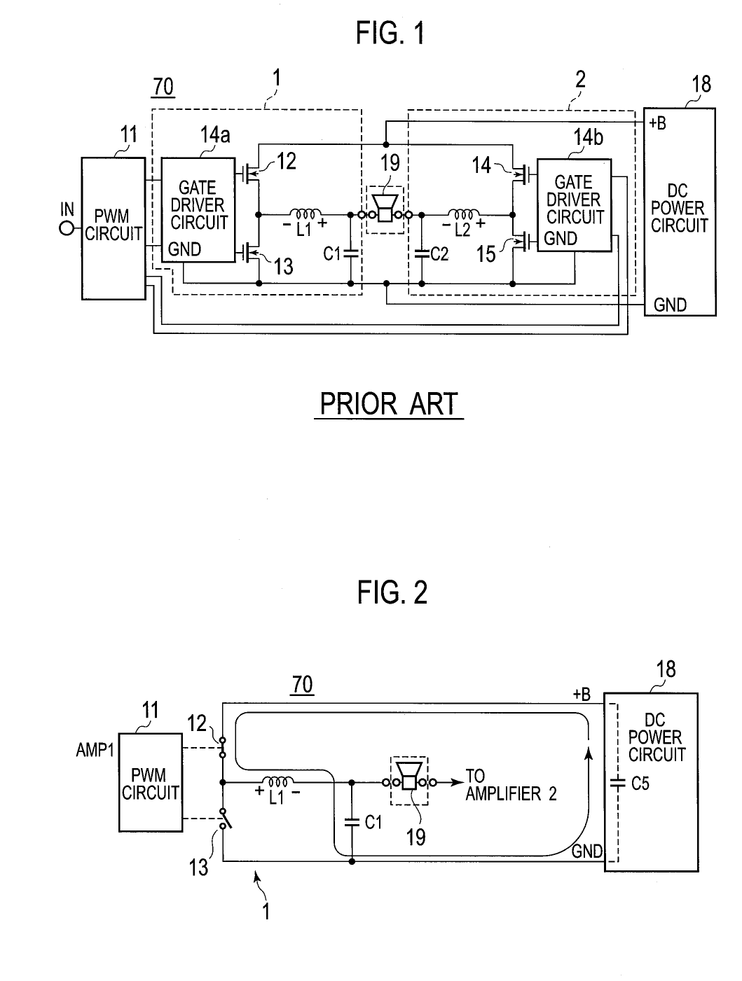

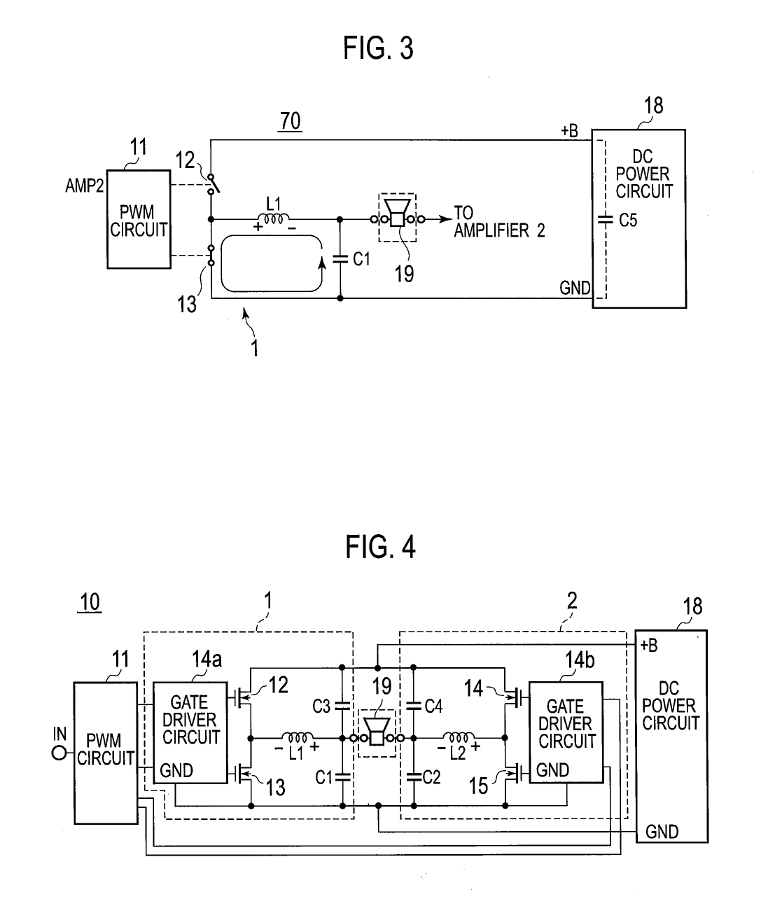

The difference between conventional digital amplifier 70 shown in FIG. 1 and digital amplifier 10 shown in FIG. 4 is that capacitors C3 and C4 are added for digital amplifier 10.

Digital amplifier 10 is an example of a digital amplifier according to embodiments. Furthermore, the digital amplifier of embodiments may be added to audio visual systems such as stand-alone systems, portable systems, in-car audio systems, and systems having audio output such as speakers.

The DC power circuit 18 is a single-power supply having a B+ (+power supply) terminal and a GND terminal. DC power circuit 18 is equivalent to a power drive unit for an amplifier of an embodiment. DC power circuit 18 can be applied to a double-power supply, which embodies a DC power circuit having a B+ (+power supply) terminal and a B− (−power supply) terminal. DC power circuit 18 produces a predetermined B+ DC voltage gained from a commercial AC power supply or a battery, and provides output from a B+ terminal.

Digital amplifier 10 has PWM circuit 11 and amplifiers 1 and 2. An analog audio signal, generated by playing CDs (Compact Discs) and so on, is inputted to an analog audio input terminal IN. PWM circuit 11 produces pulse signals having pulse widths proportional to amplitudes of analog audio signals from the analog audio input terminal IN. The pulse signals are, in addition, outputted to amplifier 1 and amplifier 2. Also, PWM circuit 11 can accommodate a circuit that directly converts digital signals (PCM signals) to PWM (pulse width modulation) signals or PDM (pulse density modulation) signals. In that case, the analog audio input terminal IN is named a digital audio input terminal.

Amplifier 1 and amplifier 2 are connected in a BTL configuration. PWM circuit 11 provides antiphase signals to gate driver circuit 14a of amplifier 1 and gate driver circuit 14b of amplifier 2. PWM circuit 11 corresponds to a signal supplier unit of this embodiment. The signal supplier unit of the present invention can utilize PDM signals instead of PWM as pulse signals related to amplitudes of audio signals included in input signals.

Amplifier 2 has the same structure as amplifier 1. Gate drive circuit 14b, FET 14 and FET 15 of CMOS devices, coil L2, and capacitors C2 and C4 in amplifier 2 correspond to respective gate drive circuit 14a, FET 12 and FET 13 of CMOS devices, coil L1, and capacitors C1 and C3 in amplifier 1 respectively. Therefore, a detailed description of amplifier 2 is omitted, and only the structure of amplifier 1 is discussed hereinafter.

Gate driver circuit 14a turns on FET 12 or FET 13, depending on the pulse signal from PMW circuit 11. FET 12 is a high-side FET. FET 13 is a low-side FET. The period when FET 12. or FET 13 is turned on is approximately proportional to the pulse width of a pulse signal from the PWM circuit 11.

The PWM pulse signal from PWM circuit 11, which includes positive and negative pulses against a midpoint voltage, is outputted to amplifier 1 and amplifier 2. FET 12 and FET 15 are turned on while a positive pulse is provided from PWM circuit 11. On the other hand, FET 13 and FET 14 are turned on while a negative pulse is provided from PWM circuit 11.

A source side of FET 12 is connected to a B+ terminal of DC power circuit 18. A drain side of FET 12 is connected to a source side of FET 13. A drain side of FET 13 is connected to the GND pattern.

FET 12 and FET 13 correspond to the switching devices in an embodiment. FET 12 and FET 13 connected in series correspond to the switching circuit in an embodiment. DC power circuit 18 corresponds to the amplifier power drive unit in an embodiment. The voltage of the power unit can be between the B-terminal and the GND.

Coil L1 and the capacitors C1 and C3 constitute a low-pass filter. One end of coil L1 is equivalent to an input side of the low-pass filter, and connected to a connecting point of FET 12 and FET 13. The other end of coil L1 is equivalent to an output side of the low-pass filter, and connected to one end of speaker 19. Capacitor C1 is placed between the other end of coil L1 and the GND pattern Capacitor C1 is placed between the other end of coil L1 and the GND pattern.

Capacitor C3 is placed between the other end of coil L1 and the source side of FET 12.

When speaker 19 has a terminal, the output terminal of the digital amplifier 10, connected to the terminal of speaker 19, corresponds to an amplifier output unit of an embodiment. On the other hand, when speaker 19 is connected to digital amplifier 10 without terminals, a line or a printed-circuit pattern in digital amplifier 10 corresponds to an amplifier output unit in an embodiment.

Theoretically, a power line is equivalent to the GND as an alternating impedance, and thus capacitors to C4 are connected in parallel as capacitors of an LC filter. In other words, considering C1 to C4 as capacitance values and not as devices, then C1+C3=C2+C4=Csum. Thereby certain properties of an output filter can be configured by Csum, coil L1, L2; and load impedance. The filter property and constant can be determined according to known methods. Further, a 1:1 ratio of capacitors C1 and C3, and of capacitors C2 and C4 (when C1+C3=C2+C4=Csum), is preferred theoretically, and to balance out alternating current loop of the noise current when the high side FET is turned on, and when the low side FET is turned on. Further, for actual devices, errors such as device errors or differences in power line patterns and impedance of GND pattern in the printed circuit exist, and the amount can be varied from this 1 to 1 ratio in order to correct these errors.

As a typical example, capacitance values for each capacitor located between a speaker and each terminal in the DC circuit are set so that each passing current level in an inaudible band is approximately the same while each switching device is turned on.

A cutoff frequency of each low-pass filter (a low-pass filter comprising L1, C1 and C3, and a low-pass filter comprising L2, C2 and C4), is set to approximately between 50 kHz and 70 kHz. In this case, it is configured that 20 kHz to be almost flat, so a frequency component to be cut off by the low-pass filter can be considered to be 20 kHz or more.

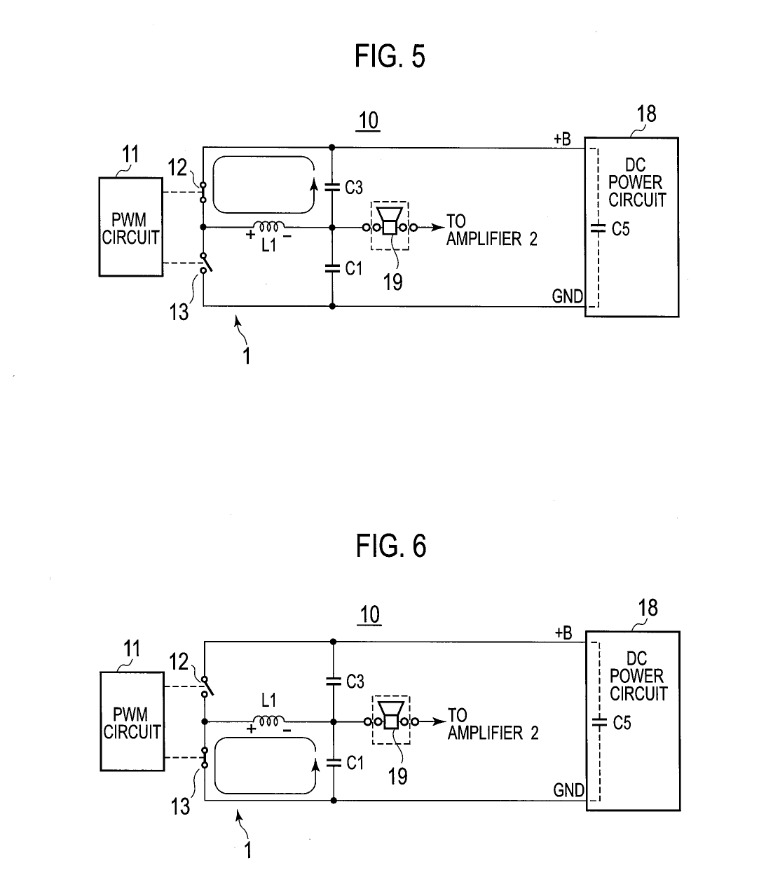

FIG. 5 and FIG. 6 illustrate a simplified method of how an AC loop of a noise current in a circuit with an LC filter in the digital amplifier 10 shown in FIG. 4 is formed while FET 12 or FET 13 is turned on. For simplicity in explanation, the circuit diagram in the side of FET 14 and FET 15 with respect to speaker 19 is omitted. In addition, DC power circuit 18 is represented as being equivalent to capacitor C5 with respect to a high-frequency noise current.

The high-frequency noise which flows through the GND pattern is halved because the high-frequency noise current from the PWM output of digital amplifier 10 is divided into a route that flows into the B+ power line and a route that flows into the GND pattern. Thereby, the GND pattern which becomes a standard of an output from a digital amplifier is maintained more clean, and thus provides an advantage for the quality of sound.

FIG. 5 and FIG. 6 show how the AC loop of a noise current, which forms while FET 12 or FET 13 is turned on, can be equalized in the high side and the low side. At the same time, the AC loop itself can be made smaller in size. Therefore, an effect to other circuits caused by electromagnetic radiation from noise of the loop can be decreased. Further, the length and area of the AC loop in both the high-side and the low-side becomes balanced. Consequently, the quality of the audio output is improved.

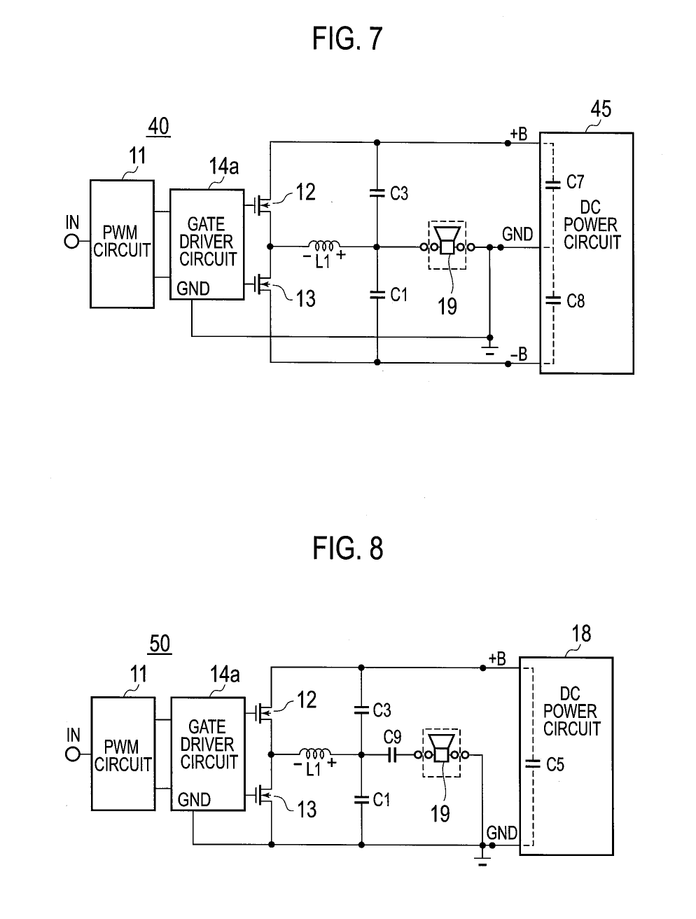

FIG. 7 is a circuit diagram to illustrate digital amplifier 40 which has a single-ended output driven by a double power supply. Each element of the digital amplifier 40 that has an equivalent element in the digital amplifier 10, is given the same reference number as the equivalent element of the digital amplifier 10 shown in FIG. 4, and its description is omitted.

DC power circuit 45 generates a B+ (+power) voltage and a B− (−power) voltage, and supplies electric power to digital amplifier 40 from each B+ terminal and B− terminal. The output of digital amplifier 40 is a single-ended output of FET 12 or FET 13 for speaker 19. Digital amplifier 40 is equipped with gate dive circuit 14a, and not with gate drive circuit 14b. The GND pattern of digital amplifier 40 is connected to the GND terminal of DC power circuit 45 and to the GND terminal of speaker 19.

In digital amplifier 40, capacitor C1 in the output LC filter is connected to the B− voltage pattern, and capacitor C3 is connected to the B+ voltage pattern. The capacitance values of capacitor C1 and C3 are determined in the same way as the capacitor C1 and C3 values of digital amplifier 10 shown in FIG. 4.

DC power circuit 45 can be considered equivalently as capacitor C7 while FET 12 is turned on, and can be considered equivalently as capacitor C8 while FET 13 is turned on. As a result, while FET 12, FET 13 are being turned on, the AC loop becomes balanced, thereby improving the quality of sound.

The single-ended output of the digital amplifier can work with not only the double power supply model shown in FIG. 7, but also with the single power supply model. FIG. 8 is a circuit diagram of digital amplifier 50, which has a single-ended output and is driven by the single power supply. Each element of digital amplifier 50 which corresponds to the elements in digital amplifier 40 is given the same reference number as digital amplifier 10 shown in FIG. 4, and its description is omitted.

Digital amplifier 50 is driven with the single power supply, DC power circuit 18 in the same way as digital amplifier 10 shown in FIG. 4. A large capacitor C9 which works as a coupling capacitor, is located between a connection point of C1 and C3, and one end of speaker 19. A drain side of FET 13, one terminal of capacitor C1 which is on the side of capacitor C3 side, and the other terminal of speaker 19 are connected to GND.

This invention is not limited to the embodiments described above and various modifications (including additions and omission) can be implemented without departing from the core of the invention.

This specification discloses embodiments of various scopes and levels. Those embodiments are not limited to the various technical scopes and to each apparatus of specific level, as described in the present specification, but may contain any thing which includes an element or any elements employing an independent action or effect, extended, or changed within the generalization of this invention. It also includes any things which employ a changed combination or some changed combinations of the elements as described.

What is claimed is:

1. A digital amplifier comprising:
a switching circuit having two switching devices connected in series, wherein both ends are connected to an amplifier power drive unit;
a gate drive circuit configured to switch the two switching devices on and off alternately;
two capacitors connected in series to ends of the switching circuit;
a coil connecting an intermediate point between the two switching devices and an intermediate point between the two capacitors; and
an output of the digital amplifier connected at an intermediate point between the two capacitors.

2. The digital amplifier according to claim 1, wherein
the two capacitors have the same capacitance value when the speaker is connected to the amplifier output terminal.

3. A digital amplifier comprising:
a first amplifier unit, comprising;
a first switching circuit having two switching elements connected in series, wherein both ends of the switching circuit are connected to an amplifier power drive unit;
a first gate driver circuit switching the two switching devices on and off alternately;
two capacitors connected in series between both ends of the first switching circuit;
a coil connecting an intermediate point between the two switching devices and an intermediate point between the two capacitors; and
a first amplifier output unit connected between the two capacitors;
a second amplifier unit, comprising;
a second switching circuit having two switching elements connected in series, wherein both ends of the switching circuit are connected to an amplifier power drive unit;
a second gate driver circuit switching the two switching devices on and off alternately;
two capacitors connected in series between both ends of the second switching circuit;
a coil connecting an intermediate point between the two switching devices and an intermediate point between the two capacitors; and
a second amplifier output unit connected between the two capacitors; and a signal supplier unit for supplying an antiphase signal to the first gate driver circuit and the second gate driver circuit.

4. The digital amplifier according to claim 3, wherein
the two capacitors of the first amplifier have the same capacitance values and the two capacitors of the second amplifier have the same capacitance values.
